(19) United States
(12) Patent Application Publication
(10) Pub. No.: US 2018/0156847 A1
(43) Pub. Date: Jun. 7, 2018

(54) CURRENT DETECTION DEVICE

(71) Applicant: KOA CORPORATION, Ina-shi, Nagano (JP)

(72) Inventors: Keishi Nakamura, Ina-shi (JP); Ryo Osawa, Ina-shi (JP); Susumu Toyoda, Ina-shi (JP); Kenji Kameko, Ina-shi (JP); Kaoru Shinoda, Ina-shi (JP)

(73) Assignee: KOA CORPORATION, Ina-shi, Nagano (JP)

(21) Appl. No.: 15/737,930

(22) PCT Filed: Jun. 27, 2016
(86) PCT No.: PCT/JP2016/069039

§ 371 Date: Dec. 19, 2017

(30) Foreign Application Priority Data
Jul. 2, 2015 (JP) 2015-133460

(51) Int. Cl. G01R 19/00

(52) U.S. Cl. CPC G01R 19/0092

(57) ABSTRACT

Provided is a compact and easily mountable current detection device in which a resistor body can be easily inserted in a current path, and a voltage value produced by the current can be easily obtained. The current detection device comprises a unit metal member (11A, 11B, 11C) that pass a current to be detected, a pair of voltage terminals (14, 14), which obtain a voltage signal from the unit metal member, and a holding member (16) that holds a plural of the unit metal members in parallel. A plural of the unit metal members (11A, 11B, 11C) is interposed between the holding member (16) and the board (17) on which a plural of wiring patterns is formed, and each pair of the voltage terminals (14, 14) of the unit metal member is connected to each wiring pattern formed on the board.

### TECHNICAL FIELD

The present invention relates to a current detection device, which detects a current by using a shunt resistor, especially suitable to detect a 3-phase current detection, such as for a 3-phase AC motor current for driving the motor installed in a motor vehicle etc.

### BACKGROUND ART

For detecting a current, which drives a 3-phase AC motor etc., for example, a magnetic detection method such as using a hall element is conventionally used. However, in the magnetic detection method, a structure that current wiring is passed through a core consisting of magnetic material is required. Further, it is necessary to install a magnetic shielding so that adjacent wiring is mutually unaffected. Therefore, there is a problem that the current detection device itself becomes a large-scale.

On the other hand, a current detection device, which uses a shunt resistor for detecting a current for driving a 3-phase AC motor etc. by detecting a voltage caused by the current passing through the resistor, is conventionally known. According to Japanese laid open patent publication 2005-218213 as an example, a technology that a current for driving a 3-phase AC motor is detected by above mentioned method, a CPU sends driving signal to an inverter circuit basing on the detected current, and the driving current is controlled, has been disclosed.

### SUMMARY OF INVENTION

### Technical Problem

According to the current detection method, which uses the shunt resistor of high resistance accuracy and low temperature coefficient of resistance, exact current detection can be possible. However, for inserting a shunt resistor in a driving current route and obtaining a voltage caused by the driving current, it is necessary to insert a resistor in the way of current route connecting an inverter circuit and a 3-phase AC motor at each current wiring of 3-phase current wirings. And, then each voltage value produced by each resistor has to be sent to a control circuit.

The invention has been made basing on above-mentioned circumstances. Thus, an object of the invention is to provide a compact and easily mountable current detection device, in which a plural of resistors can be inserted into a plural of phases of current paths, and voltage signals produced by the plural of currents can be taken out easily.

### Solution to Problem

The current detection device of the invention includes a unit metal member that passes a current to be detected; a pair of voltage terminals that obtain a voltage signal from the unit metal member; and a holding member that holds a plural of the unit metal members in parallel. A plural of the unit metal members is interposed between the holding member and the board, on which a plural of wiring patterns are formed, and each pair of voltage terminals of the unit metal member is connected to each wiring pattern formed on the board.

According to the present invention, the unit metal member includes a resistor body and a pair of voltage terminals to obtain a voltage signal produced between both ends of the resistor body, and a plural of the unit metal members is held by the holding member in parallel. Therefore, when detecting a 3-phase motor current, which drives a motor vehicle, as an example, because 3-phase unit metal members are held in parallel, the current detection device can be connected to 3-phase bus bars easily, and a compact design can be obtained easily. Then, the current detection device can be mountable in a narrow space such as an engine room in a motor vehicle.

### BRIEF DESCRIPTION OF DRAWINGS

FIG. 1 is a perspective view of the current detection device of the embodiment 1.

FIG. 2 is an exploded perspective view of the current detection device before the board is mounted.

FIG. 3 is an exploded perspective view of the current detection device when the unit metal member is being mounted.

FIG. 4 is a perspective view of the current detection device of the embodiment 2.

FIG. 5 is an exploded perspective view of the current detection device before the board is mounted.

FIG. 6 is an exploded perspective view of the current detection device when the unit metal member is being mounted.

FIG. 7 is a view, which illustrates an example of a circuit diagram.

### DESCRIPTION OF EMBODIMENTS

Embodiments of the present invention will be described below with referring to FIG. 1 through FIG. 7. Like or corresponding parts or elements will be denoted and explained by same reference characters throughout views.

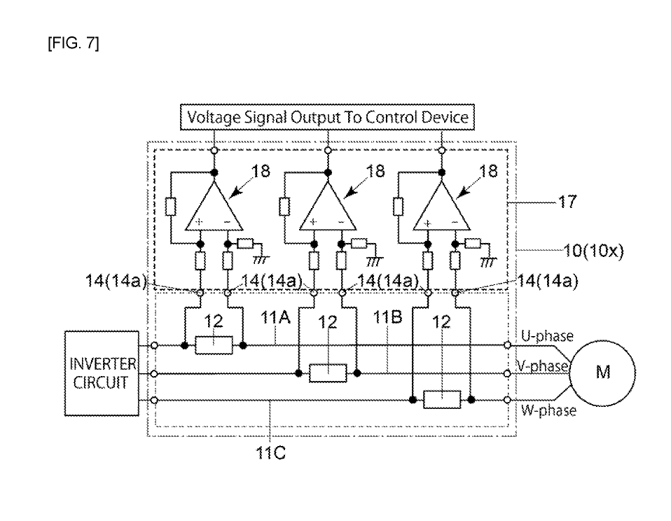

FIGS. 1-3 illustrate a current detection device of the embodiment 1. The device 10 detects 3-phase currents such as for driving a 3-phase AC motor etc. The device 10 is used so as to be inserted between outputs of an inverter circuit and inputs of a motor M (see FIG. 7). That is, three unit metal members (shunt resistors) 11A,11B,11C, through which currents to be detected pass, are inserted in a current route between outputs of an inverter circuit, which supplies driving currents, and U-phase, V-phase, and W-phase inputs of a 3-phase AC motor.

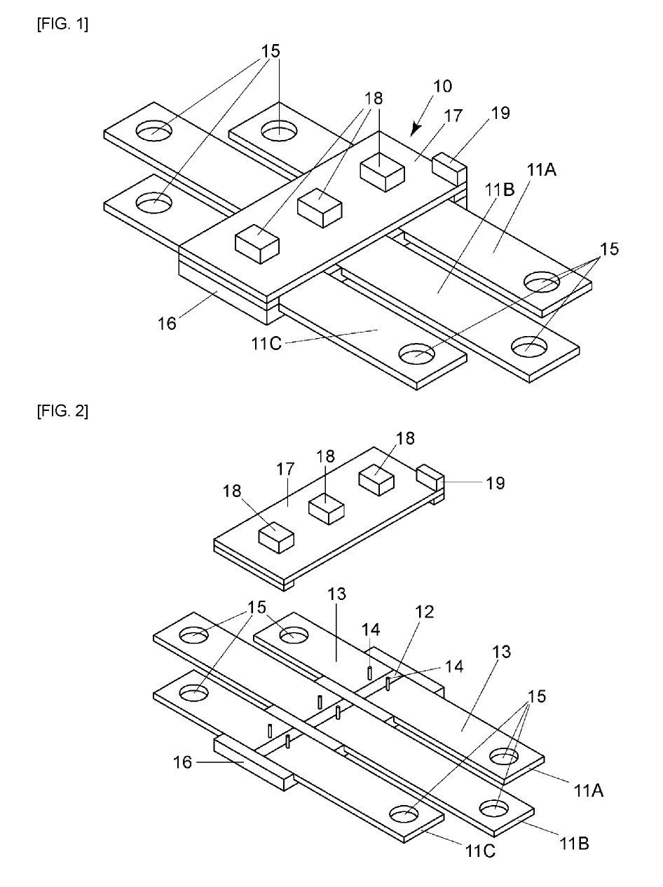

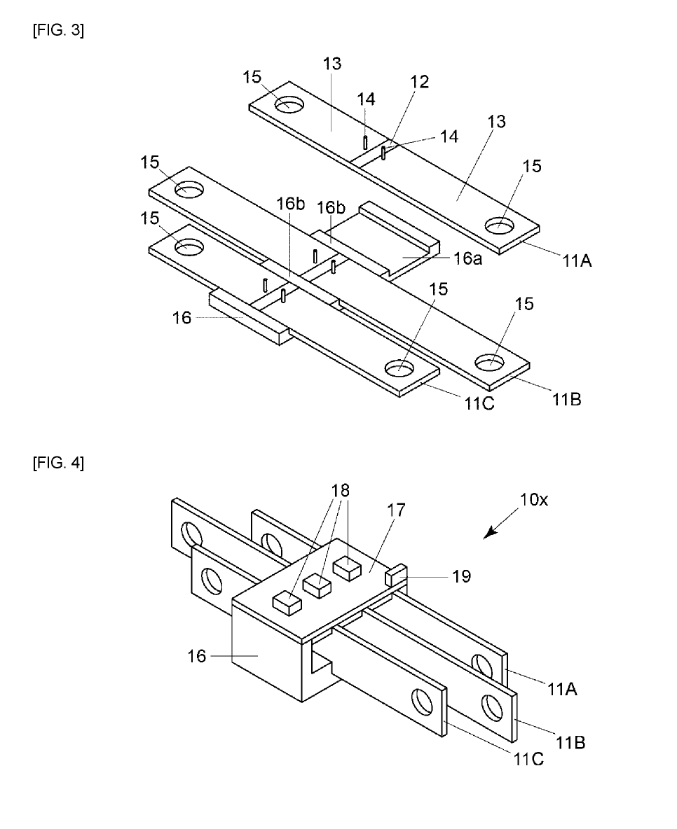

Each shunt resistor 11A, 11B, 11C is provided with a resistor body 12 and electrodes (terminal members) 13 fixed at both ends of the resistor body 12 (see FIGS. 2-3). The resistor body 12 consists of metal material such as Cu—Mn system alloy, Cu—Ni system alloy, or Ni—Cr system alloy etc., which has a far smaller temperature coefficient of resistance than Cu etc. The electrode (terminal member) 13 consists of high conductivity metal material such as Cu, Cu system alloy, Al etc. A pair of voltage terminals 14 is elected on the electrodes (terminal members) at both ends of the resistor body 12.

Further, the shunt resistor comprising a resistor body 12 and a pair of electrodes (terminal members) 13 is described as an example of the “unit metal member”. However, the “unit metal member” may be a structure that a pair of voltage terminals are elected on one piece of metal plate consisting of resistive alloy material such as Cu—Ni system alloy. Even though plate shaped unit metal member is shown as an example. However, the unit metal member may be rod shaped or line shaped.

The shunt resistor 11A,11B,11C is provided with a hole 15 for fixing and being connected to a current wiring (bus bar etc., for example), which is current path connecting the inverter circuit to the motor M, by bolt fastening etc. Connection between the unit metal member and the current wiring (bus bar etc., for example) may be made by not only bolt fastening but also welding etc. By making both ends of the unit metal member connect to an end of the bus bar etc. easily, the current detection device can be easily mounted.

Length of the unit metal members (shunt resistors) may be same. However, as shown in FIG. 1 etc., the unit metal members of two different length is provided. That is, the shunt resistor 11B is longer than the shunt resistor 11A and 11C by the fixing hole portion 15. Therefore, when connecting the shunt resistors to 3-phase bus bars of current path for current detection, fixing work such as bolt fastening etc. may become easy.

The current detection device 10 is constructed as an integral unit so that the shunt resistors 11A,11B,11C are interposed between the holding member 16 and the board 17. The board 17 is integrated with the holding member 16 and the shunt resistors 11A,11B,11C by bolt fastening or adhesives. Therefore, the board 17 can be said to be a part of the holding member 16.

The holding member 16 is formed by insulative resin etc. Concave portions 16a are formed in the holding member 16, and a portion including the resistor body 12 of the shunt resistor is accommodated in the concave portion 16a (see FIG. 3). Therefore, strength of the joint between the resistor body 12 and the electrode (terminal member) 13 can be kept strong. Also, the holding member 16 holds the unit metal members at surroundings of the pair of the voltage terminals 14.

The holding member 16 holds the unit metal members except both end parts thereof. Convex portions 16b are formed between the concave portions 16a,16a in the holding member 16 so that electrical insulation is secured between adjacent shunt resistors (see FIG. 3). In the embodiment, the holding member 16 holds the unit metal members (shunt resistors) 11A,11B,11C disposed in parallel in the direction of width direction.

The voltage that is a product of a current passing through the resistor body 12 and a resistance of the resistor body 12, is produced between the voltage terminals 14,14, which are disposed on both sides of the resistor body 12. The pair of voltage terminals 14,14 is connected to a wiring pattern (not shown) formed on the board 12 for transmitting the detected voltage signal. The wiring patterns are connected to electronic parts 18 and connector 19 mounted on the board 17 (see FIG. 2). The wiring pattern is respectively formed corresponding to each voltage signal of U-phase, V-phase, and W-phase obtained by each corresponding unit metal member.

The connector 19 is provided for outputting voltage signals or control signals etc. basing on detected voltage signals etc. to other control device. The electronic parts 18 includes amplifiers, A/D converters, and control circuits, if necessary. Accordingly, the voltage produced at both ends of the resistor body 12 by the driving current etc. is outputted to between voltage terminals 14,14, a process such as amplification etc. is added to the detected voltage signal if necessary, and the voltage signal is outputted to the other control device connected to the connector 19.

FIGS. 4-6 illustrates a current detection device of the embodiment 2. In the current detection device 10x, the holding member 16 holds the unit metal members (shunt resistors) 11A,11B,11C disposed in parallel in the direction of thickness direction. As a result, the current detection device 10x can be smaller.

In the embodiment, the concave portion 16a is formed for holding a plate shaped shunt resistor in the direction of thickness direction. A portion including the resistor body 12 of the unit metal member (shunt resistor) 11A,11B,11C is accommodated in the concave portion 16a. And, a plural of the unit metal resistors (shunt resistor) corresponding to 3-phases is held in the holding member 16. Convex portions 16b are formed between the concave portions 16a in the holding member 16 so that electrical insulation is secured between adjacent shunt resistors (see FIG. 6).

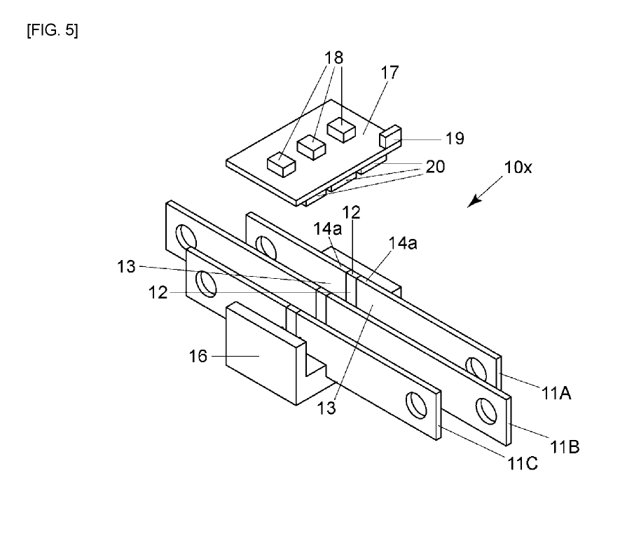

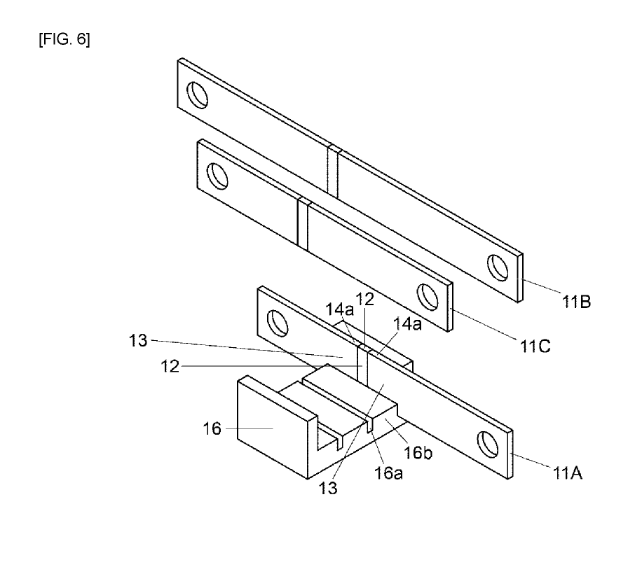

On the back surface of the board 17, a spacer 20, which holds the shunt resistors at an interval, is formed. In the embodiment, the shunt resistors 11A,11B,11C are interposed between the holding member 16 and the board 17 and integrated as an unit. On upper surface of both sides of the resistor body 12 of the shunt resistor 11A,11B,11C, a pair of voltage terminal portions 14a is formed. The voltage terminal portion 14a is connected to wiring patterns (not shown) formed on the board 17 (see FIG. 5). Voltage detection terminals may be elected on voltage terminal portion 14a as well as the embodiment 1.

The wiring patterns are connected to the electronic parts 18 and the connector 19. Accordingly, in the embodiment, the voltage produced at both ends of the resistor body 12 by the current is picked up by a pair of voltage terminals 14,14, a process such as amplification etc. is added to the voltage signal if necessary, and the voltage signal is outputted to the other control device connected to the connector 19. The wiring patterns are respectively formed corresponding to each voltage signal obtained by each corresponding unit metal member as well as the embodiment 1.

FIG. 7 illustrates an example of circuit diagram of the current detection device 10,10x. The shunt resistors 11A,11B,11C corresponding to 3-phases are held by the holding member 16, and a pair of voltage terminals 14(14a) for obtaining a voltage produced at both ends of the resistor body 12 is connected to wiring patterns on the board 17 corresponding to 3-phase voltage signals. On the board 17, when an amplifier is adopted as an electronic parts, 3-phases voltage signals of the pairs of voltage terminals 14(14a) are amplified and controlled to be a favorable level, and outputted to a control device.

According to the current detection device, the unit metal members corresponding to a plural of phases are interposed in parallel between the holding member 16 and the board 17, and, circuits for outputting voltage signals corresponding to the plural of phases are respectively formed on the board 17, and these are integrally constructed as a compact unit. Then, when connecting the current detection device 10,10x to a plural of bus bars in a route between an inverter circuit and a motor, for example, the plural of detected voltage signals corresponding to the plural of phases can be picked up from the connector 19 formed on the board 17.

Since, the current detection device 10,10x is compact and easily mountable, then even in a narrow space, for example, such as in an engine room of a motor vehicle, where 3-phase AC motor is installed, both ends of the unit metal members 11A,11B,11C can be easily connected to the plural of phases of current paths such as bus bars etc. and the voltage signals can be respectively outputted from the wiring patterns on the board 17.

In the embodiments, a 3-phase structure of current detection device corresponding to a 3-phase AC motor has been shown. However, according to object current to be detected, any phase current detection device having more than 2 phases of unit metal members (shunt resistors) can be possible.

Although embodiments of the invention have been explained, however the invention is not limited to above embodiments, and various changes and modifications may be made within the scope of the technical concept of the invention.

### INDUSTRIAL APPLICABILITY

The invention can be applicable for current detections, which uses a shunt resistor. Especially, the invention is applicable for current detections, where a plural phase of current wirings to be detected is disposed. Specifically, the invention is applicable for 3-phase current detections, for example, where a 3-phase AC motor is installed in a motor vehicle etc., 3-phase power source current detections and others.

1. A current detection device comprising:
a unit metal member that passes a current to be detected;
a pair of voltage terminals that obtain a voltage signal from the unit metal member; and
a holding member that holds a plural of the unit metal members in parallel.

2. The current detection device of claim 1, wherein the unit metal member is plate-shaped, and the holding member holds the unit metal members in parallel in direction of thickness.

3. The current detection device of claim 1, wherein at least two kinds of length of the unit metal members are provided.

4. The current detection device of claim 1, wherein a board, on which a plural of wiring patterns is formed for transmitting a plural of voltage signals, is provided.

5. The current detection device of claim 4, wherein the wiring pattern is formed on each voltage signal, which is obtained from each unit metal member.

6. The current detection device of claim 5, wherein a plural of the unit metal members is interposed between the holding member and the board, on which the plural of wiring patterns is formed, and each pair of voltage terminals of the unit metal member is connected to each wiring pattern on the board.

7. The current detection device of claim 1, wherein the holding member holds the unit metal member except both end parts thereof.
